(19) United States
(12) Patent Application Publication
(10) Pub. No.: US 2021/0379800 A1
(43) Pub. Date: Dec. 9, 2021

(54) IMPRINT DEVICE, ARTICLE MANUFACTURING METHOD, AND MEASURING METHOD FOR IMPRINT DEVICE

(71) Applicant: CANON KABUSHIKI KAISHA, Tokyo (JP)

(72) Inventor: Fumiaki Kitayama, Tokyo (JP)

(21) Appl. No.: 17/324,310

(22) Filed: May 19, 2021

(30) Foreign Application Priority Data
Jun. 4, 2020 (JP) 2020-097411

(51) Int. Cl. B29C 33/72; B29C 59/00; B29C 59/02; G03F 7/00

(52) U.S. Cl. CPC B29C 33/72; B29C 59/002; B29K 2995/0074; G03F 7/0002; B29C 59/022

(57) ABSTRACT

An imprint device that can simply detect an abnormality such as dirt of a mold chuck is provided. The imprint device includes a holding mechanism configured to hold a mold, a mold shape correcting mechanism configured to modify a shape of the mold, a mold shape measuring unit configured to measure the shape of the mold, and a determination unit configured to determine whether there is dirt on a mold holding surface of the holding mechanism or the mold based on mold modification characteristics which are measured by the mold shape measuring unit with respect to target mold modification values in the mold shape correcting mechanism.

### BACKGROUND OF THE INVENTION

### Field of the Invention

The present invention relates to an imprint device and so on.

### Description of the Related Art

Recently, downsizing of semiconductor devices has progressed and an imprinting technique of applying a resin onto a substrate and curing the resin in a state in which the resin is pressed with an original pattern on a mold has been used for a semiconductor device manufacturing method. A photo-curing method is known as an example of the imprinting technique. In an imprint device employing a photo-curing method, first, a mold is conveyed to a mold holding device. A substrate is conveyed to a substrate holding device.

The mold holding device includes a mold holding mechanism that holds a mold and a mold shape correcting mechanism that modifies a shape of the mold. The substrate holding device includes a substrate holding mechanism that hold a substrate and a driving mechanism that can move the substrate in a planar direction. Then, a photo-curing resin is applied to a pattern formation area on the substrate. Then, in processes before and/or after the resin is pressed with the mold, alignment correction of the substrate and the mold is performed using a mold shape correcting mechanism.

In Japanese Unexamined Patent Application Publication (Translation of PCT Application) No. 2008-504141, alignment correction is performed by mechanically applying forces to side surfaces of a mold using actuators of a mold shape correcting mechanism to deform a pattern on the mold. Piezoelectric actuators are used as the actuators.

Thereafter, a resin is cured by irradiating the resin with ultraviolet light, and then the mold is released. Accordingly, a pattern of the resin is formed on a substrate.

In such an imprint device, a mold shape correcting mechanism that corrects shape errors in a pattern which is generated in semiconductor processes is generally provided in a holding device that holds a mold. The mold shape correcting mechanism includes driving units and sensors for controlling amounts of driving of the driving unit and is installed at a plurality of positions surrounding outer peripheral portions of the mold.

In this case, the driving unit modifies the shape of the mold to correct a pattern shape which is formed on the mold by applying external forces to the mold. At this time, since the pattern shape affects the overlap accuracy between patterns, high-precision correction of equal to or less than several nm is required to cope with pattern fining. For example, Japanese Unexamined Patent Application Publication (Translation of PCT Application) No. 2008-504141 discloses a correction device that corrects a shape of a mold by applying compressive forces to side surfaces of the mold.

In the mold holding mechanism of the imprint device, a mold is held using a mold chuck (a mold chucking mechanism) that directly chucks (for example, vacuum-chucks) a mold. The correction device described in Japanese Unexamined Patent Application Publication (Translation of PCT Application) No. 2008-504141 corrects the mold shape in a state in which the mold is chucked by the mold chuck in a direction corresponding to a mold pressing direction.

Accordingly, a frictional force in a direction of the compressive force which is applied by the mold shape correcting device is generated on a contact surface between the mold and the mold chuck. That is, the mold shape correcting device corrects the shape of the mold by applying a force larger than the frictional force to the mold and rubbing the contact surface.

At this time, for example, if dirt such as foreign substance is attached to the mold, and if the mold is held by the mold chuck, the dirt on the mold is transferred to the mold chuck. In a state in which the mold chuck or the mold has dirt thereon, the state of the contact surface between the mold and the mold chuck is different from that in a state without dirt and thus the frictional force is also different.

When the dirt is sticky or the like, the mold is less likely to slide with respect to the mold chuck. When the mold is less likely to slide, satisfactory shape correction may not be able to be performed using the mold shape correcting mechanism and thus the overlap accuracy deteriorates.

When the mold is less likely to slide with respect to the mold chuck, the mold shape correction using the mold shape correcting mechanism may not be able to be performed as instructed, so that the correcting operation may have to be performed a plurality of times. As a result, a correction time increases and productivity deteriorates.

Therefore, an objective of the present invention is to provide an imprint device that can detect an abnormality such as adhesion of foreign substance on a mold chuck using a simplified method.

### SUMMARY OF THE INVENTION

In order to achieve the afore mentioned objective, an imprint device according to an aspect of the present invention includes: a holding mechanism configured to hold a mold;

a mold shape correcting mechanism configured to modify a shape of the mold;

at least one processor or circuit configured to function as:

a mold shape measuring unit configured to measure the shape of the mold; and

a determination unit configured to determine whether there is dirt on a mold holding surface of the holding mechanism or the mold based on mold modification characteristics which are measured by the mold shape measuring unit with respect to target mold modification values in the mold shape correcting mechanism.

Further features of the present invention will become apparent from the following description of exemplary embodiments with reference to the attached drawings.

### BRIEF DESCRIPTION OF THE DRAWINGS

FIG. 1 is a diagram illustrating a configuration of an imprint device according to an embodiment.

FIG. 2 is a diagram illustrating an example of an arrangement of a mold shape correcting mechanism.

FIG. 3 is a flowchart illustrating an operation sequence which is performed by the imprint device.

FIG. 4 is a flowchart illustrating an operation sequence of determining dirt of a mold chuck.

FIG. 5 is a diagram illustrating an example of a mold magnification setting pattern at the time of detecting dirt of a mold chuck.

FIG. 6 is a diagram illustrating a relationship between target mold modification magnification values and actual mold magnification values when a mold chuck or the like is not dirty.

FIG. 7 is a diagram illustrating a relationship between target mold modification magnification values and actual mold magnification values when a mold chuck or the like gets dirty.

### DESCRIPTION OF THE EMBODIMENTS

Hereinafter, with reference to the accompanying drawings, favorable mode of the present invention will be described using Embodiments. In each diagram, the same reference signs are applied to the same members or elements, and duplicate description will be omitted or simplified.

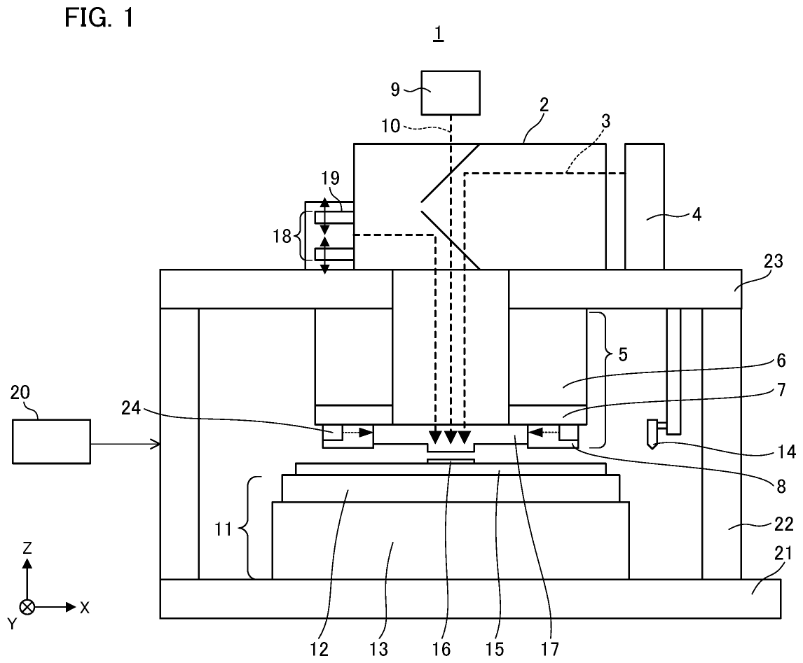

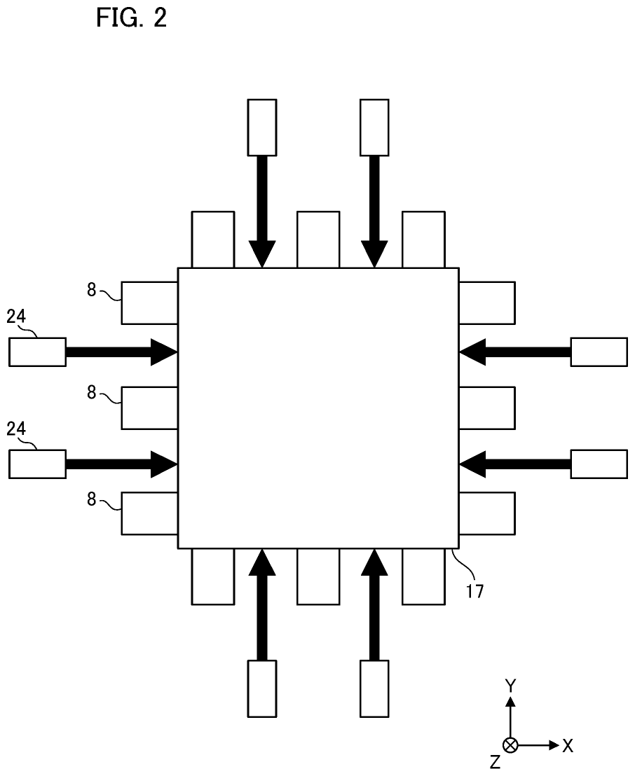

FIG. 1 is a diagram illustrating a configuration of an imprint device according to a first embodiment. FIG. 2 is a diagram illustrating an example of an arrangement of a mold shape correcting mechanism. The imprint device 1 includes a substrate (a wafer) 15, a mold 17, an illumination device 2, a substrate holding device 11, a mold holding device 5 as a holding mechanism that holds a mold, a resin applying device 14, and an alignment measuring device 18.

The imprint device 1 further includes a control device 20 and an observation device 9 that observes an imprinted state of a resin 16 on the substrate 15.

The substrate 15 is a subject substrate and, for example, a single-crystal silicon wafer or a silicon-on-insulator (SOI) wafer is used. An imprinting material, which is to be formed by the mold, and which includes a UV-curing resin and is hereinafter simply referred to as a “resin”, is applied to the subject surface of the substrate 15.

The substrate holding device 11 is a device that can hold and move the substrate 15 in an X-axis direction, a Y-axis direction, and a θ-axis direction. The substrate holding device 11 can move to a position at which the substrate can be exchanged with a substrate conveying device at the time of exchange of a substrate, or can move to a position under the resin applying device 14 for applying the resin 16 on the substrate 15. The substrate holding device 11 also performs an alignment correcting operation by moving the substrate 15 in a translational shift direction or a rotational direction with respect to the mold 17 at the time of transfer of a pattern. The substrate holding device 11 includes a substrate chuck 12 and a substrate stage 13.

The substrate chuck 12 holds the substrate 15, for example, using a vacuum chucking pad that is a mechanical holding means which is not illustrated. The substrate chuck 12 is held on the substrate stage 13 using a vacuum chucking pad that is a mechanical holding means which is not illustrated. The substrate stage 13 is a driving mechanism that moves in the X-axis direction, the Y-axis direction, and the θ-axis direction (rotation around an Z axis) for the purpose of alignment correction in a translational shift direction or a rotational direction of the substrate 15 with respect to the mold 17.

The driving mechanism in the X-axis direction, the Y-axis direction, and the θ-axis direction may include a plurality of driving mechanisms such as a coarse driving mechanism and a fine driving mechanism. The driving mechanism may further include a driving mechanism for position adjustment in the Z-axis direction or a tilting mechanism for correcting an inclination of the substrate 15.

The resin applying device 14 is a device that applies the resin 16 to the substrate 15. The resin applying device 14 includes a resin ejection nozzle which is not illustrated and drops the resin 16 onto the substrate 15 from the resin ejection nozzle.

The resin 16 has a feature of being cured by irradiation with ultraviolet light 3. The resin may have a feature that it is cured by heat. An amount of the resin 16 ejected can be determined based on a necessary resin thickness, a density of a pattern which is transferred, or the like.

The mold holding device 5 is a device that holds and fixes the mold 17 and transfers an uneven pattern of the mold 17 to the substrate 15. The mold holding device 5 includes a mold driving mechanism 6, a mold chuck 7, and a mold shape correcting mechanism 8.

The mold chuck 7 is a mechanism that holds and fixes or releases the mold 17 using a vacuum chucking pad which is a mechanical holding means which is not illustrated or the like. The mold driving mechanism 6 is a driving mechanism that determines a gap between the substrate 15 and the mold 17 when an uneven pattern of the mold 17 is transferred to the substrate 15, and drives the mold in the Z-axis direction.

Since high-precision positioning is required at the time of transferring an uneven pattern, the mold driving mechanism 6 may include a plurality of driving mechanisms such as a coarse driving mechanism and a fine driving mechanism. The mold driving mechanism 6 may include a position adjusting mechanism for the X-axis direction, the Y-axis direction, or the θ-axis direction (rotation around the Z axis) in addition to the Z-axis direction and a tilting mechanism that correcting the inclination of the mold 17.

The mold shape correcting mechanism 8 is a mechanism that corrects the shape of the mold 17 by modification and is provided at a plurality of positions around the outer circumferential portion of the mold 17 as illustrated in FIG. 2. The mold shape correcting mechanism 8 is configured to modify and correct the shape of the mold 17 by applying a force or a displacement to the side surface of the mold 17. By correcting the shape of the mold 17 by modification, it is possible to perform alignment correction of the magnification and distortion or the like of the substrate 15 and the mold 17 at the time of transferring a pattern.

A mold shape measuring unit 24 is provided in the mold holding device 5. The mold shape measuring unit 24 is provided in the outer circumferential portion of the mold 17 on the mold chuck 7 and measures the position (shape) of the mold outer circumferential position. In this embodiment, as illustrated in FIG. 2, a plurality of mold shape measuring units 24 are disposed around the mold 17. The mold shape measuring unit may employ, for example, an interferometer, a capacitance sensor, or an imaging device such as a CCD camera or a linear imaging sensor.

The alignment measuring device 18 includes an imaging unit such as a CCD camera and a measurement light emitting unit 19. In order for the alignment measuring device 18 to measure a shape of a shot area on the substrate 15 and the shape of the mold 17, it is necessary to measure a plurality of alignment marks which are formed on the substrate 15 and the mold 17.

It is preferable to provide a plurality of imaging devices such as CCD cameras in the alignment measuring device 18 such that the plurality of alignment marks can be simultaneously measured.

The positions of the alignment marks on the mold 17 may be different between molds, for example, due to manufacturing errors of the molds. Therefore, a mechanism that drives the alignment measuring device 18 may be provided to observe the alignment marks on the mold 17.

A halogen lamp, an LED, a laser, or the like is used as an illumination light source used for the measurement light emitting unit 19 of the alignment measuring device 18. Alignment measurement light from the measurement light emitting unit 19 illuminates the alignment marks (not illustrated) which are formed on the substrate 15 and the mold 17. Then, by measuring reflected light thereof, the alignment measuring device 18 measures a misalignment and a shape error in a magnification or the like in the X-axis direction, the Y-axis direction, and the θ-axis direction of the substrate 15 and the mold 17.

The observation device 9 includes an imaging unit such as a CCD camera and an observation light emitting unit. A halogen lamp, an LED, a laser, or the like can be used as an illumination light source used for the observation light emitting unit. By applying resin observation light 10 to the substrate and imaging reflected light from the resin molded on the substrate 15 by the mold 17, it is possible to ascertain whether there is a defect or the like in the molded pattern.

The control device 20 is a control means that controls operations and adjustments of the constituent elements of the imprint device 1 and the like. For example, the control device 20 includes a computer and a storage device, is connected to the constituent elements of the imprint device 1 via lines, and can perform control of the constituent elements in accordance with a computer program stored in a memory which is not illustrated.

The imprint device 1 includes a base plate 21 that supports the substrate holding device 11, a support plate 23 that supports the mold holding device 5, and pillars 22 that support the support plate 23 and the like.

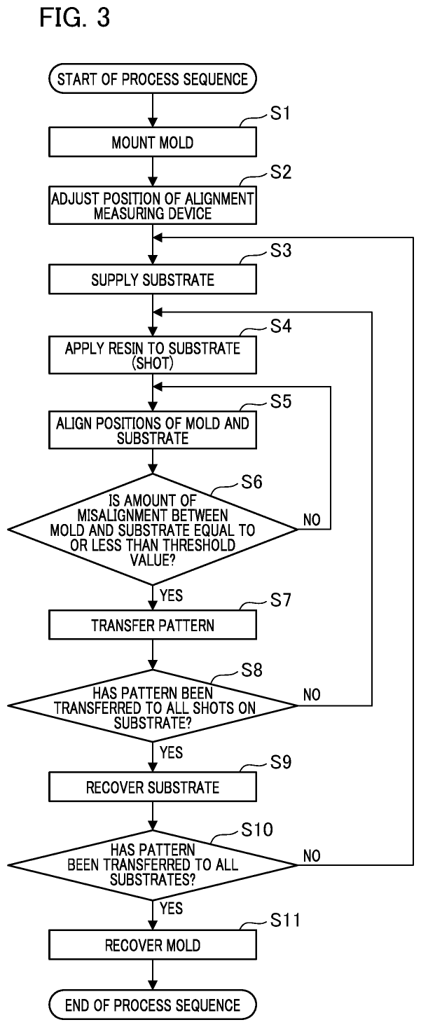

FIG. 3 is a flowchart illustrating an operation sequence when patterns are molded on a plurality of substrates 15 by causing the control device 20 of the imprint device 1 to execute a computer program stored in the memory which is not illustrated. It is assumed that the same mold 17 is used for one lot including the plurality of substrates 15.

First, when the control device 20 starts the operation sequence, the mold 17 is carried to the mold holding device 5 using a mold carrying mechanism which is not illustrated and the mold 17 is mounted on the mold holding device 5 by chucking the mold 17 using the mold chuck 7 (Step S1).

Then, positioning of a measuring system of the alignment measuring device 18 is performed such that a plurality of alignment marks on the mold 17 can be measured (Step S2). This step is performed because there is a likelihood that the alignment marks formed on the mold 17 will not be included in the field of view of the alignment measuring device 18 due to manufacturing error or the like of the mold.

When no alignment mark can be measured in this step, positioning of the alignment measuring device 18 is performed by finding an alignment mark on the mold 17 while changing a measurement position of the alignment measuring device 18.

Then, a substrate 15 is supplied to the substrate holding device 11 (Step S3). The substrate 15 is carried using a substrate carrying mechanism which is not illustrated and the substrate 15 is chucked and held using the substrate chuck 12.

Then, a resin 16 is applied to the substrate 15 on the substrate holding device 11 (Step S4). That is, the substrate holding device 11 is driven for scan while applying the resin using the resin applying device 14 such that one desired shot area out of a plurality of shot areas (subject areas) on the substrate 15 is located at an application position of the resin applying device 14.

Then, the mold 17 and the substrate 15 are positioned (Step S5).

This positioning is performed in a state in which the mold 17 is pressed on the resin 16 on the substrate 15 by the mold driving mechanism 6.

That is, overlap of an alignment mark formed on the mold 17 and an alignment mark formed on the substrate 15 is detected by the alignment measuring device 18. By detecting overlap of the two marks, an amount of misalignment of the shape in the translational (XY) direction, the θ direction, the magnification, and the like of the mold 17 with respect to the substrate 15 can be calculated. Correction is performed by the substrate holding device 11 and the mold shape correcting mechanism 8 such that misalignment is removed based on he calculated amount of misalignment.

Then, the overlap of the alignment marks formed on the mold 17 and the alignment marks formed on the substrate 15 is observed (measured) using the alignment measuring device 18 and it is determined whether the amount of misalignment is equal to or less than a threshold value (Step S6). When the amount of misalignment is not equal to or less than the threshold value, the alignment adjusting operation of Steps S5 and S6 are repeated until the amount of misalignment is equal to or less than the threshold value, and positioning is performed such that the amount of misalignment between the mold 17 and the substrate 15 is equal to or less than the threshold value (closed positioning).

When the amount of misalignment between the mold 17 and the substrate 15 is equal to or less than the threshold value and a time required for filling unevenness of the pattern with the resin 16 has elapsed, the pattern is transferred to the shot areas on the substrate 15 (Step S7). That is, the pattern transfer is performed by applying ultraviolet light 3 from the light source 4 to cure the resin 16 in a state in which the pattern of the mold 17 is in contact with the resin 16.

Thereafter, by detaching the cured resin 16 and the mold 17 from each other using the mold driving mechanism 6, the pattern transfer on the substrate 15 is completed. This pattern transfer is performed on all the shot areas on the substrate 15 (Step S8).

When the pattern transfer has been completed for all the shot areas on the substrate 15, the control device 20 recovers the substrate 15 from the substrate holding device 11 using the substrate carrying mechanism (Step S9). Then, when it is determined in Step S10 that there is no new substrate 15 to be processed in the current lot, the control device 20 recovers the mold 17 from the mold holding device 5 using the mold carrying mechanism (Step S11) and ends the operation sequence.

Here, it is assumed that the mold chuck 7 gets dirty. As one factor for the mold chuck 7 getting dirty, a case in which foreign matter attached to the mold 17 is transferred to the mold chuck 7, a case in which dirty matter remaining in a device space is attached to the mold chuck 7, and the like can be considered.

When the mold chuck 7 gets dirty, a frictional force between the mold chuck 7 and the mold 17 may increase and the mold 17 is less likely to slide with respect to the mold chuck 7. In this state, even if it is intended to deform the mold 17 using the mold shape correcting mechanism 8, the mold 17 may be less likely to slide due to dirt, and the mold may be less likely to be deformed and may not be deformed as targeted.

At this time, the mold shape correcting mechanism 8 has to perform work corresponding to the friction (the load) increased due to the dirty and a correction value which can be used for modification of the mold decreases. As a result, alignment accuracy between the mold 17 and the substrate 15 deteriorates. When the mold 17 is less likely to slide with respect to the mold chuck 7, the mold is not deformed as targeted using the mold shape correcting mechanism 8 and thus Steps S5 to S6 in FIG. 3 are repeatedly performed a plurality of times.

As a result, the time required for alignment adjustment (shape correction) of the mold increases and productivity decreases. An example in which the mold chuck 7 has got dirty has been described above, and the same is true when the mold 17 gets dirty.

Accordingly, there is demand for a method of simply detecting dirt of the mold 17 and the mold chuck 7.

A method of detecting dirty of the mold chuck according to an embodiment of the invention will be described below.

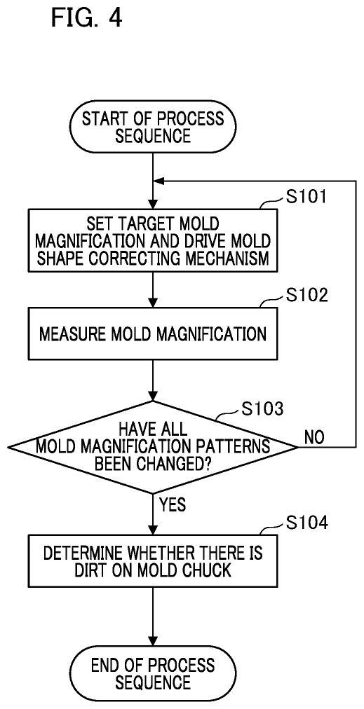

FIG. 4 is a flowchart illustrating an operation sequence of determining whether there is dirt on the mold chuck according to this embodiment. This operation sequence is performed in a state in which the mold 17 is held by the mold holding mechanism. In this embodiment, it is assumed that modification by the mold shape correcting mechanism is performed using a plurality of magnification modification patterns. 100491 First, the control device 20 sets a target mold magnification to a predetermined magnification and modifies the shape of the mold 17 (the mold magnification) using the mold shape correcting mechanism 8 (Step S101). At this time, for the modification of the mold using the mold shape correcting mechanism, open control for driving the mold shape correcting mechanism 8 with a correction force corresponding to a target magnification is performed instead of determining a difference between the mold magnification and a shot magnification and repeatedly performing the modification until the difference is equal to or less than a threshold value. That is, the operations of Steps S5 and S6 in FIG. 3 are not repeatedly performed and the operation of Step S5 is performed only once.

Then, the shape of the mold 17 (the magnification of the mold 17) is measured using the mold shape measuring unit 24 (Step S102). Since the mold shape measuring unit 24 is disposed at a plurality of positions in the X direction and the Y direction as illustrated in FIG. 2, it is possible to accurately measure the sizes in the X direction and the Y direction of the mold 17.

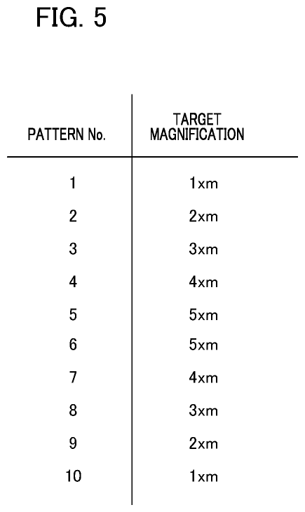

Then, the control device 20 determines whether all the plurality of magnification modification patterns have been processed (Step S103). When all the plurality of magnification modification patterns have not been processed, the operation sequence returns to Step S101 and the mold modification and mold modification measurement using another magnification modification pattern are performed. In this embodiment, 10 magnification modification patterns illustrated in FIG. 5 are used as the plurality of magnification modification patterns.

FIG. 5 is a diagram illustrating an example of mold magnification setting patterns at the time of detecting dirt on the mold chuck. In Pattern Nos. 1 to 5, the target mold modification magnification increases in the order of the pattern numbers. In Pattern Nos. 6 to 10, the target mold modification magnification decreases in the order of the pattern numbers.

The predetermined magnification modification patterns are not limited to these patterns as long as a relationship between the target mold magnification in Step S101 and the actual measurement result in Step S102 can be seen. For example, patterns in which the target mold magnification decreases in Pattern Nos. 1 to 5 and the target mold magnification increases in Pattern Nos. 6 to 10 may be used.

The number of patterns is not limited to ten and the number of patterns may be, for example, one. It is possible to detect an abnormality such as dirt with higher reliability as the number of patterns increases.

In Step S103, it is determined whether modification and measurement have been performed for all of a predetermined number of mold magnification modification patterns. When the determination result is NO, the operation sequence returns to Step S101. When the determination result is YES, the control device 20 determines whether the mold chuck 7 has got dirty from the relationship between the target mold modification magnification set in Step S101 and the actual mold modification magnification measured in Step S102 (Step S104).

That is, Step S104 serves as a determination unit that determines whether there is dirt on the mold holding surface of the holding mechanism or the mold based on the mold modification characteristics (an amount of modification) measured by the mold shape measuring unit with respect to the target mold modification value instructed by the mold shape correcting mechanism. Here, the target modification value means a target value of an amount of modification and may be a target shape after being deformed.

A time (a modification rate) required for modification of the mold by a predetermined amount with respect to the target mold modification value instructed by the mold shape correcting mechanism may be measured as the mold modification characteristics by the mold shape measuring unit.

When the modification rate of the mold is less than a predetermined value, it may be determined that there is dirt.

As described above, this embodiment is characterized in that a mold magnification is changed by the mold shape correcting mechanism when the determination unit determines whether there is dirt.

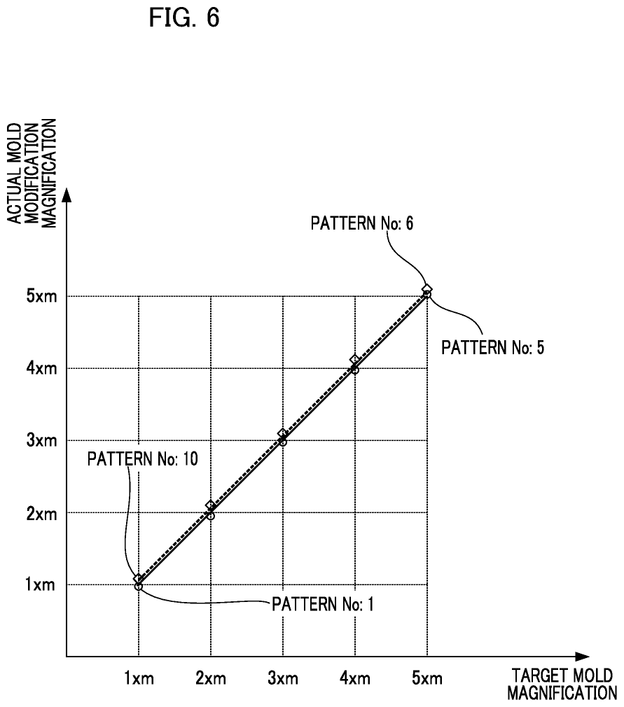

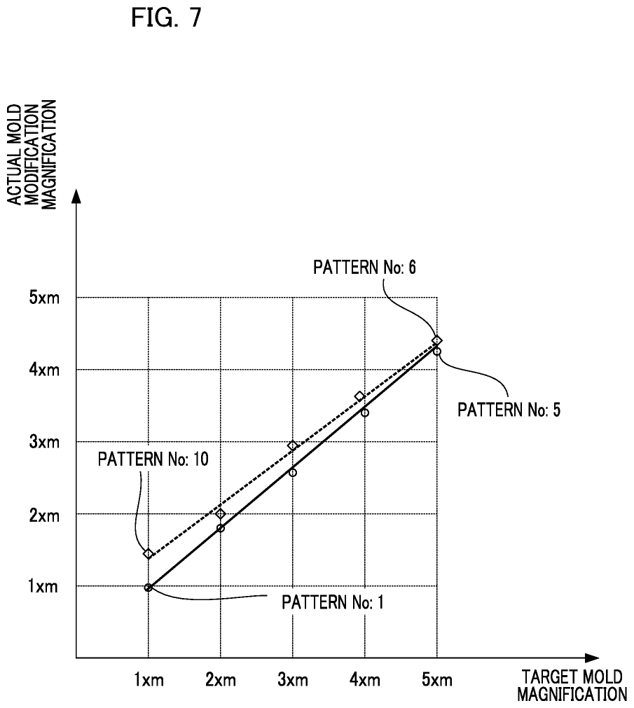

FIGS. 6 and 7 are diagrams illustrating a relationship between the target mold magnification and the actually measured mold magnification (mold modification characteristics), where the horizontal axis represents the target mold magnification and the vertical axis represents the actual mold magnification. FIG. 6 is a diagram illustrating the relationship between the target mold modification magnification value and the actual mold magnification when the mold chuck or the like has not got dirty, and FIG. 7 is a diagram illustrating the relationship between the target mold modification magnification value and the actual mold magnification when the mold chuck or the like has got dirty.

When the mold chuck 7 has not got dirty, the mold 17 is likely to slide with respect to the mold chuck 7. The mold 17 is deformed according to the target magnification when the mold 17 is deformed using the mold shape correcting mechanism 8. Since target magnification≈actual modification magnification is satisfied, the slope of a straight line (=actual modification magnification/target magnification) of the graph illustrated in FIG. 6 is substantially 1. As illustrated in FIG. 6, the curves (the mold modification characteristics) substantially match each other by a round trip of the change in magnification.

On the other hand, when the mold chuck 7 or the mold 17 has got dirty and the mold 17 is less likely to slide with respect to the mold chuck 7, the target magnification cannot be achieved even if the mold 17 is deformed using the mold shape correcting mechanism 8 (target magnification>actual modification magnification).

Accordingly, the slope of the straight line (=actual modification magnification/target magnification) is less than 1 as illustrated in FIG. 7.

In the operations in which the target magnification of the mold 17 increases (Pattern Nos. 1 to 5) and the operations in which the target magnification of the mold 17 decreases (Pattern Nos. 6 to 10), since the direction in which the mold 17 slides with respect to the mold chuck 7, that is, the direction of friction, is different, there is a likelihood that the frictional force will be changed due to the dirty of the mold chuck 7 or the mold 17.

That is, as illustrated in FIG. 7, the slope of the graph (a solid line in FIG. 7) in the direction in which the mold magnification increases (Pattern Nos. 1 to 5) and the slope of the graph (a dotted line in FIG. 7) in the direction in which the mold magnification decreases (Pattern Nos. 6 to 10) may be different from each other.

Whether there is dirty in the mold chuck 7 or the like can be determined, for example, using Expression (1).

Actual modification magnification/target magnification<Th1 (1)

Here, Th1 is a threshold value for determining whether there is dirt in the mold chuck 7 or the like. In a state in which there is no dirt in the mold chuck 7 or the like, the left side of Expression (1) is assumed to be, for example, 1 in design. On the other hand, when there is dirt in the mold chuck 7 or the like, the load increases and thus the left side of Expression (1) is less than 1 or Th1.

In another method, whether there is dirt in the mold chuck 7 or the like may be determined, for example, using Expression (2).

|K1−K2|<Th2 (2)

K1=(actual modification magnification/target magnification) in Pattern Nos. 1 to 5 (3)

K2=(actual modification magnification/target magnification) in Pattern Nos. 6 to 10 (4)

When there is dirt in the mold chuck 7 or the like, there is a high likelihood that the slope will be different in the operations in which the target magnification of the mold 17 increases (Pattern Nos. 1 to 5, the solid line in FIG. 7) and the operations in which the target magnification of the mold 17 decreases (Pattern Nos. 6 to 10, the dotted line in FIG. 7) as illustrated in FIG. 7. Here, a phenomenon which causes a hysteresis is used to determine whether there is dirt in the mold chuck 7 or the like.

In this way, in this embodiment, the mold shape in one or more patterns is deformed using the mold shape correcting mechanism when it is determined whether there is dirt. Since the mold shape in a plurality of patterns is measured using the mold shape measuring unit and it is determined whether there is dirt based on the mold modification characteristics measured by the mold shape measuring unit, it is possible to determine whether there is dirt with high accuracy.

The mold modification characteristics include amounts of mold modification and mold modification rates measured by the mold shape measuring unit with respect to the target mold modification values.

When it is determined that there is dirt in the mold chuck 7 or the like, a process of cleaning a contact portion between the mold chuck 7 and the mold 17 and the like is performed. Cleaning of the mold chuck 7 or the like can be realized by bringing a cleaning member into contact with the mold chuck 7 or the like, for example, as described in Japanese Patent Laid-Open No. 2012-186390.

With this method, when dirt in the mold chuck 7 or the like has been detected, it is possible to notify of the fact by rapidly displaying it on an operation screen or the like, to rapidly perform cleaning of the mold chuck 7 or the like manually or automatically, and thus to cause improvement in an operation rate of the device.

In this embodiment, the amount of modification of the mold 17 is measured using the mold shape measuring unit 24, but the amount of modification of the mold 17 may be measured using the alignment measuring device 18. For example, in the process of adjusting the position of the alignment measuring device 18 in Step S2 of FIG. 3, for example, the dirt determining sequence of the mold chuck 7 or the like in FIG. 4 may be performed when a time required for positioning is equal to or greater than a predetermined time.

In the alignment positioning step which is performed by the alignment measuring device 18 in Steps S5 and S6 of FIG. 3, for example, the dirt determining sequence of the mold chuck 7 or the like in FIG. 4 may be performed when the time required for positioning is equal to or greater than a predetermined time. The mold shape may be measured using the observation device 9 instead of measuring the mold shape using the mold shape measuring unit 24. Alternatively, the dirt determining sequence of the mold chuck 7 or the like in FIG. 4 may be performed whenever a predetermined number of lots are processed.

An article (a semiconductor IC element, a liquid crystal display element, an MEMS, or the like) manufacturing method using the aforementioned imprint device will be described below. The article manufacturing method according to this embodiment includes a mold shape correcting step of modifying a shape of a mold held by the holding mechanism of the imprint device and a mold shape measuring step of measuring the shape of the mold.

The article manufacturing method further includes a determination step of determining whether there is dirt in a mold holding surface of the holding mechanism or the mold based on an amount of modification of the mold measured in the mold shape measuring step with respect to the target mold modification value instructed in the mold shape correcting step.

The article manufacturing method further includes a removal step of removing the dirt which is determined in the determination step and a pattern forming step of forming a pattern on a substrate using the mold after the dirt has been removed in the removal step.

The pattern forming step includes a step of pressing the substrate to which the imprinting material has been applied and a step of releasing the mold using the aforementioned imprint device.

An article is manufacturing by performing post-processing steps (steps of manufacturing articles from the pressed substrate). The post-processing steps include etching, resist detachment, dicing, bonding, packaging, and development.

With the article manufacturing method according to the invention, since it is possible to simply prevent deterioration in overlap accuracy between a mold and a shot area or deterioration in productivity due to an increase of a correction time in a magnification correcting mechanism, it is possible to enhance the yield and to manufacture articles with higher quality.

While the present invention has been described with reference to exemplary embodiments, it is to be understood that the invention is not limited to the disclosed exemplary embodiments. The scope of the following claims is to be accorded the broadest interpretation to encompass all such modifications and equivalent structures and functions. In addition, as a part or the whole of the control according to this embodiment, a computer program realizing the function of the embodiment described above may be supplied to the detection apparatus or the lithography apparatus through a network or various storage media. Then, a computer (or a CPU, an MPU, or the like) of the detection apparatus or the lithography apparatus may be configured to read and execute the program. In such a case, the program and the storage medium storing the program configure the present invention.

This application claims the benefit of Japanese Patent Application No. 2020-097411 filed on Jun. 4, 2020, which is hereby incorporated by reference herein in its entirety.

1. An imprint device comprising:
a holding mechanism configured to hold a mold;
a mold shape correcting mechanism configured to modify a shape of the mold;
at least one processor or circuit configured to function as:
a mold shape measuring unit configured to measure the shape of the mold; and
a determination unit configured to determine whether there is dirt on a mold holding surface of the holding mechanism or the mold based on mold modification characteristics which are measured by the mold shape measuring unit with respect to target mold modification values in the mold shape correcting mechanism.

2. The imprint device according to claim 1, wherein a magnification of the mold is changed by the mold shape correcting mechanism when the determination unit determines whether there is dirt.

3. The imprint device according to claim 1, wherein the mold modification characteristics include mold modification amounts or mold modification rates measured by the mold shape measuring unit with respect to the target mold modification values.

4. The imprint device according to claim 1, wherein the determination unit determines whether there is dirt by modifying mold shapes with a plurality of patterns using the mold shape correcting mechanism and measuring the mold shapes of the plurality of patterns using the mold shape measuring unit.

5. The imprint device according to claim 1, wherein the mold shape measuring unit measures an outer circumferential portion of the mold.

6. The imprint device according to claim 1, wherein the mold shape measuring unit measures a plurality of marks on the mold.

7. The imprint device according to claim 6, wherein the marks include alignment marks which are formed on the mold to align a position of the mold.

8. An article manufacturing method using an imprint device, the imprint device including a holding mechanism configured to hold a mold, a mold shape correcting mechanism configured to modify a shape of the mold, at least one processor or circuit configured to function as:
a mold shape measuring unit configured to measure the shape of the mold, and a determination unit configured to determine whether there is dirt on a mold holding surface of the holding mechanism or the mold based on mold modification characteristics which are measured by the mold shape measuring unit with respect to target mold modification values in the mold shape correcting mechanism, the article manufacturing method comprising:
determining whether there is dirt using the imprint device;
removing the dirt determined in the determining;
forming a pattern on the substrate using the mold after the dirt is removed in the removing; and
developing the substrate on which the pattern is formed in the forming.

9. A measuring method for an imprint device, comprising:
correcting a mold shape by modifying a shape of the mold which is held by a holding mechanism of the imprint device;
measuring the shape of the mold; and
determining whether there is dirt on a mold holding surface of the holding mechanism or the mold based on mold modification characteristics which are measured in the measuring with respect to target mold modification values which are designated in the correcting.
